(19) United States
(12) Patent Application Publication
(10) Pub. No.: US 2026/0231743 A1
(43) Pub. Date: Aug. 6, 2026

(54) SEMICONDUCTOR DEVICE STRUCTURE AND MANUFACTURING METHOD THEREOF

(71) Applicant: Winbond Electronics Corp., Taichung City (TW)

(72) Inventors: Hung-Yu Wei, Kaohsiung (TW); Hao-Chuan Chang, Kaohsiung City (TW)

(73) Assignee: Winbond Electronics Corp., Taichung City (TW)

(21) Appl. No.: 19/245,424

(22) Filed: Jun. 23, 2025

(30) Foreign Application Priority Data
Feb. 3, 2025 (TW) 114103896

(51) Int. Cl. H10W 10/17; H10D 84/01; H10W 10/00

(52) U.S. Cl. CPC H10W 10/17; H10D 84/0151; H10W 10/0145

(57) ABSTRACT

Provided is a semiconductor device structure including the following. A first transistor device and a second transistor device include a first contact structure and a second contact structure closely adjacent to each other and in a surface region of a substrate. Also, an isolation structure extends between the first contact structure and the second contact structure in the substrate, and has at least one laterally protruding structure laterally protruding with respect to a vertically extending body portion of the isolation structure. The at least one laterally protruding structure is at least partially located below the first contact structure and the second contact structure.

### CROSS-REFERENCE TO RELATED APPLICATION

This application claims the priority benefit of Taiwan application serial no. 114103896, filed on Feb. 3, 2025. The entirety of the above-mentioned patent application is hereby incorporated by reference herein and made a part of this specification.

### BACKGROUND

### Technical Field

The disclosure relates to a semiconductor device structure and a manufacturing method thereof, and particularly relates to a semiconductor device structure and a manufacturing method thereof that can suppress leakage along an isolation structure.

### Related Art

Generally, a semiconductor device structure includes multiple interconnected semiconductor devices. Isolation structures are disposed between adjacent semiconductor devices to block undesired leakage paths. However, during the process of forming the isolation structures, charges are easily formed within the isolation structures, accumulating charges of opposite polarity around the isolation structures and forming conductive channels. This adversely affects the isolating function of the isolation structures and further the performance of the semiconductor device structure.

### SUMMARY

The disclosure provides a semiconductor device structure including the following. A first transistor device and a second transistor device include a first contact structure and a second contact structure closely adjacent to each other and in a surface region of a substrate. Also, an isolation structure extends between the first contact structure and the second contact structure in the substrate, and has at least one laterally protruding structure laterally protruding with respect to a vertically extending body portion of the isolation structure, in which the at least one laterally protruding structure is at least partially located below the first contact structure and the second contact structure.

The disclosure provides a manufacturing method of a semiconductor device structure including the following. An isolation structure is formed in a substrate, in which the isolation structure has at least one laterally protruding structure laterally protruding with respect to a vertically extending body portion of the isolation structure. Also, a first transistor device and a second transistor device are formed on both sides of the isolation structure, in which the first transistor device and the second transistor device include a first contact structure and a second contact structure spaced apart by the isolation structure and in a surface region of a substrate, in which the at least one laterally protruding structure of the isolation structure is at least partially located below the first contact structure and the second contact structure.

### BRIEF DESCRIPTION OF THE DRAWINGS

FIGS. 1 and 2 are cross-sectional schematic views illustrating a portion of a semiconductor device structure according to some embodiments of the disclosure.

FIGS. 3A to 3H are cross-sectional schematic views illustrating a series of intermediate structures during a process for forming an isolation structure shown in FIGS. 1 and 2 according to some embodiments of the disclosure.

FIGS. 4A to 4C, FIGS. 5, and 7A to 7C are cross-sectional schematic views illustrating the isolation structure according to some embodiments of the disclosure.

FIGS. 6A to 6C are cross-sectional schematic views illustrating a series of intermediate structures during a process for forming the isolation structure shown in FIG. 5 according to some embodiments of the disclosure.

### DESCRIPTION OF THE EMBODIMENTS

The disclosure provides an improved isolation structure, whose special structure can effectively block surrounding leakage paths. This isolation structure may be applied to various semiconductor device structures, as illustrated below through several embodiments. However, after understanding, persons skilled in the art should realize that the isolation structure may be applied to other types of semiconductor device structures and may function equally well.

A semiconductor device structure 10 may be a logic circuit, for example, a driving circuit of a memory array. Multiple semiconductor devices are connected to provide various functions of the semiconductor device structure 10. The semiconductor devices may include a transistor device 100.

The transistor device 100 is formed on a surface region of a substrate 102, and includes a gate structure 104 disposed on the substrate 102. The gate structure 104 includes a gate electrode 106 and a gate dielectric layer 108 extending between the gate electrode 106 and the substrate 102. The gate structure 104 includes a hard mask layer 110 stacked on the gate electrode 106, and includes a gap wall 112 extending along sidewalls of the hard mask layer 110, the gate electrode 106, and the gate dielectric layer 108. The transistor device 100 further includes drain/source structures 114 disposed on both sides of the gate structure 104. The drain/source structures 114 may be provided by doped regions in the surface region of the substrate 102. The drain/source structures 114 may be epitaxial structures formed in surface recesses of the substrate 102.

In addition to the transistor device 100, the semiconductor device structure 10 further includes an isolation structure 116 disposed between adjacent transistor devices 100. More specifically, the isolation structure 116 extends between the adjacent drain/source structures 114 of neighboring transistor devices 100, and reaches into the substrate 102 from the surface of the substrate 102. In this way, the isolation structure 116 filled with insulating material may electrically isolate the adjacent drain/source structures 114, thereby avoiding crosstalk between the adjacent transistor devices 100.

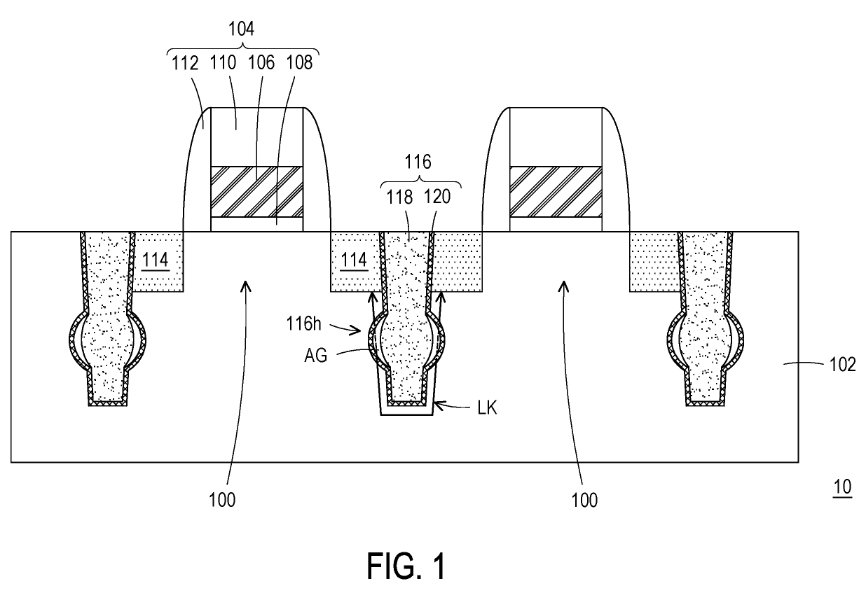

The depth of the isolation structure 116 is greater than the depth of the drain/source structures 114, such that the bottom surface of the isolation structure 116 is lower than the bottom surface of the drain/source structures 114. In addition, the isolation structure 116 has at least one laterally protruding structure (hump) 116h at the middle section and/or bottom portion below the bottom surface of the drain/source structures 114. In FIG. 1, the isolation structure 116 has only a single laterally protruding structure 116h located at the middle section between two adjacent transistor devices 100. The top end of the laterally protruding structure 116h is lower than the bottom surface of the drain/source structures 114, while the bottom end of the laterally protruding structure 116h is higher than the bottom surface of the isolation structure 116.

The laterally protruding structure 116h protrudes outward from the sidewall of the isolation structure 116, such that the isolation structure 116 has a greater width at the laterally protruding structure 116h compared to the body portions above and below. The isolation structure 116 gradually narrows from the topmost end downward, except for the locally greater width at the laterally protruding structure 116h. In addition, although illustrated as having an arc surface, the laterally protruding structure 116h may also have surfaces with other shapes.

During the process of forming the isolation structure 116h, fixed charges, such as positive charges, are easily formed within the isolation structure 116h. Charges of opposite polarity, such as negative charges, may be induced around the isolation structure 116h. These charges accumulated at the sidewalls and the bottom surface of the isolation structure 116h may inadvertently form a leakage path LK, electrically connecting the drain/source structures 114 on both sides of the isolation structure 116h. Nevertheless, the laterally protruding structure 116h of the isolation structure 116 may cut off the leakage path LK, thereby ensuring that the drain/source structures 114 on both sides may be electrically isolated from each other. As one mechanism, the laterally protruding structure 116h may extend through the leakage path LK, effectively interrupting the leakage path LK. As another mechanism, as will be described in more detail below, the laterally protruding structure 116h significantly reduces charge accumulation around the laterally protruding structure 116h due to an air gap AG within, thereby interrupting the leakage path LK.

The isolation structure 116 includes an insulating fill material 118 and an insulating liner 120 lining the sidewalls and the bottom surface of the insulating fill material 118. The insulating fill material 118 may be silicon nitride, while the insulating liner 120 may be formed by silicon oxide. During the formation of the insulating fill material 118, fixed charges, such as positive charges, are easily formed within the insulating fill material 118. These fixed charges may induce charges of opposite polarity, such as negative charges, in the surrounding substrate 102 through the insulating liner 120. Nevertheless, the laterally protruding structure 116h of the isolation structure 116 may prevent these induced charges from continuously extending to the drain/source structures 114 on both sides and forming the leakage path LK. One reason for this effect is the formation of an air gap AG between the insulating fill material 118 and the insulating liner 120 at the laterally protruding structure 116h of the isolation structure 116. The dielectric constant of the air gap AG is far lower than the dielectric constant of the insulating liner 120, thereby effectively reducing the opposite polarity charges induced by the fixed charges in the insulating fill material 118 around the exterior of the laterally protruding structure 116h. In addition, the formation of the air gap AG causes the insulating fill material 118 to be spaced apart from the insulating liner 120 by a greater distance at the laterally protruding structure 116h, which similarly reduces the induced opposite polarity charges around the exterior of the laterally protruding structure 116h. By preventing the induced charges around the exterior of the laterally protruding structure 116h, the leakage path LK is blocked at the laterally protruding structure 116h. Therefore, the effect of the isolation structure 116 in electrically isolating adjacent transistor devices 100 can be further ensured, and crosstalk between adjacent memory cells can be prevented.

The semiconductor device structure 20 includes a dynamic random access memory (DRAM) array, which includes multiple access transistors AT formed in multiple active regions 202 of a substrate 200. Although not shown, the DRAM array further includes multiple storage capacitors respectively connected to access transistors AT. To control the access transistors AT and connect the access transistors AT to the storage capacitors, signal lines, bit line contact structures, and capacitor contact structures are further disposed between the substrate 200 and the storage capacitors.

Each access transistor AT is defined at an intersection of a word line WL and an active region 202. The word line WL penetrating the active region 202 serves as the gate of the access transistor AT, while the portions of the active region 202 on both sides of each intersecting word line WL serve as the drain and source of the access transistor AT. The active region 202 is shared by a pair of access transistors AT, respectively penetrated by two word lines WL, and the portion of each active region 202 between the intersecting two word lines WL serves as the common drain/source for the two access transistors AT.

The word line WL is formed in the trench extending downward from the surface of the substrate 200 into the substrate 200, and includes a gate electrode 204 and a gate dielectric layer 206 covering the sidewalls and the bottom surface of the gate electrodes 204. The gate electrode 204 is re-etched so that the top surface thereof is lower than the surface of the substrate 200, and an insulating plug 208 is backfilled into the trench to cover the top surface of the gate electrode 204. On the other hand, the top end of the gate dielectric layers 206 may extend to a height substantially flush with the surface of the substrate 200. In addition, the gate electrode 204 contacts the gate dielectric layer 206 via a conductor liner 210. The conductor liner 210 may improve the adhesion between the gate electrode 204 and the gate dielectric layer 206, and/or provide work function adjustment functionality.

The portions of the active region 202 on both sides of the intersecting word lines WL serve as the drain/source of the access transistors AT. More specifically, these portions of the respective active regions 202 are doped to form doped regions 212, to provide the drain and source of the access transistors AT. The conductivity type of the doped region 212 is opposite (or complementary) to the conductivity type of the active region 202.

In embodiments where each active region 202 is shared by a pair of access transistors AT, the doped region 212 intersecting between the two word lines WL of each active region 202 serves as the common drain/source for the two access transistors AT, and is connected to a bit line BL extending above the substrate 200 via a bit line contact structure 214. The bit line contact structure 214 may extend downward from above the substrate 200 to a depth below the surface of the substrate 200, and reach into the doped region 212 to serve as the common drain/source. The bit line contact structure 214 laterally expands and extends into top regions of the word lines WL, for example, extending into the gate dielectric layers 206 and insulating plugs 208 of the word lines WL. On the other hand, the bit line BL extends along the top surface of the bit line contact structure 214. The bit line BL includes a conductor layer 216 and a conductor liner 218 extending between the conductor layer 216 and the bit line contact structure 214.

Another drain/source (the doped region 212) of each access transistor AT is connected to an unshown storage capacitor through a capacitor contact structure 220. Where each active region 202 is shared by a pair of access transistors AT, the capacitor contact structures 220 are disposed on the intersecting doped regions 212 on both sides of the two word lines WL of each active region 202. As an example, the capacitor contact structure 220 may include a lower contact structure 222 and an upper contact structure 224 stacked on the lower contact structure 222. The upper contact structure 224 includes a conductor structure 226 and a conductor liner 228 covering the sidewalls and the bottom surface of the conductor structure 226. Furthermore, the total height of the capacitor contact structure 220 is greater than the total height of the bit line contact structure 214 and the bit line BL. The bit line BL extends between the substrate 200 and the storage capacitor (not shown) disposed above the capacitor contact structure 220.

The bit line contact structure 214, the bit line BL, and the capacitor contact structure 220 are embedded in at least one dielectric layer. The at least one dielectric layer includes a dielectric liner 230 extending along the surface of the substrate 200 and an interlayer dielectric layer 232 formed on the dielectric liner 230. Although the interlayer dielectric layer 232 is shown as a single-layer structure, the interlayer dielectric layer 232 may actually be a multi-layer structure.

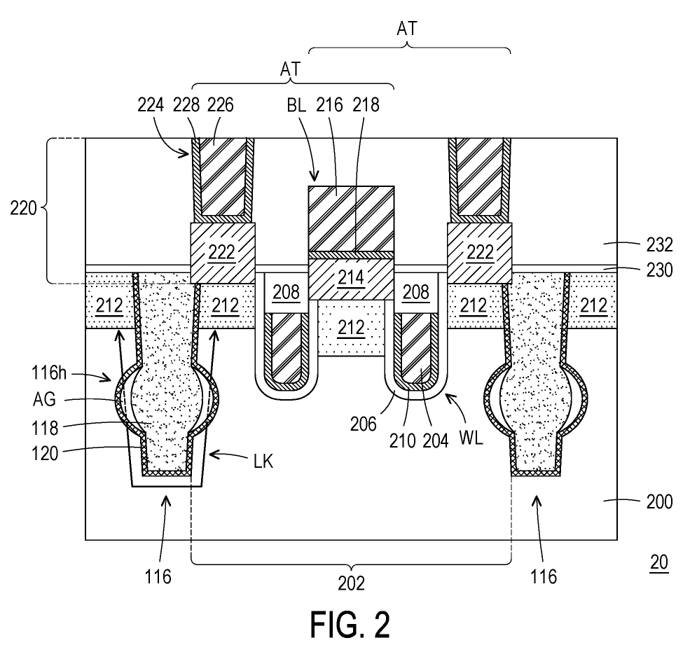

The isolation structure 116 shown in FIG. 2 is used to define each active region 202, and to prevent crosstalk between the access transistor AT defined in each active region 202 and the access transistor AT defined in an adjacent active region 202. The isolation structure 116 may be used to prevent unintentional electrical connection between the doped regions 212 on both sides thereof via the leakage path LK. More specifically, the laterally protruding structure 118 of the isolation structure 116 extends through the leakage path LK to block the leakage path LK, and/or by forming the air gap AG in the laterally protruding structure 118, the structure can significantly reduce the surrounding charge accumulation to block the leakage path LK. Therefore, the isolation structure 116 can more effectively isolate the doped regions 212 on the both sides thereof, that is, the doped region 212 connected to the storage capacitor (not shown) via the corresponding capacitor contact structure 220. For the same reason, the isolation structure 116 can effectively isolate the doped regions 212 serving as common drain/source in adjacent active regions 202 from each other. By blocking these leakage paths, crosstalk between adjacent memory cells can be effectively prevented, thus enabling the DRAM to operate more energy-efficiently and with better data retention capability.

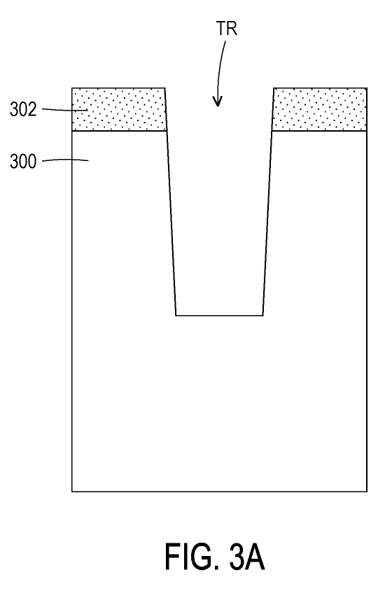

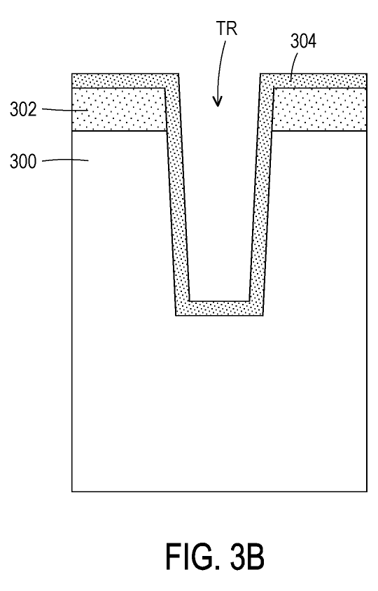

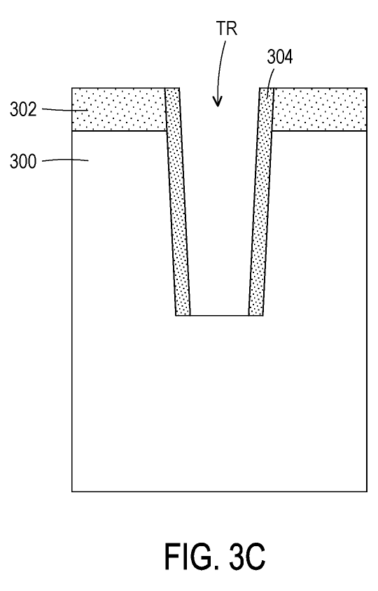

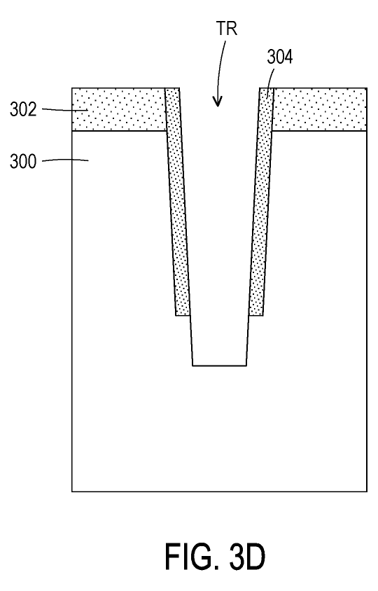

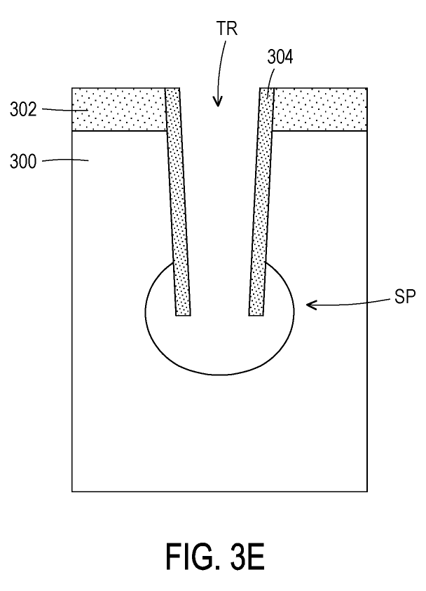

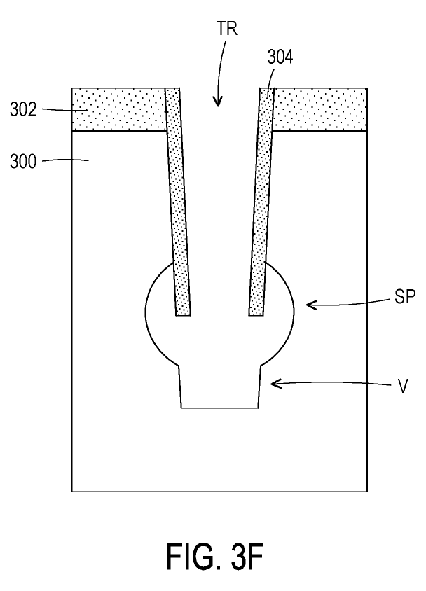

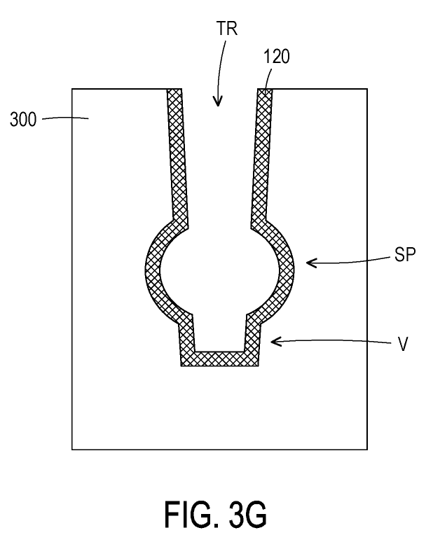

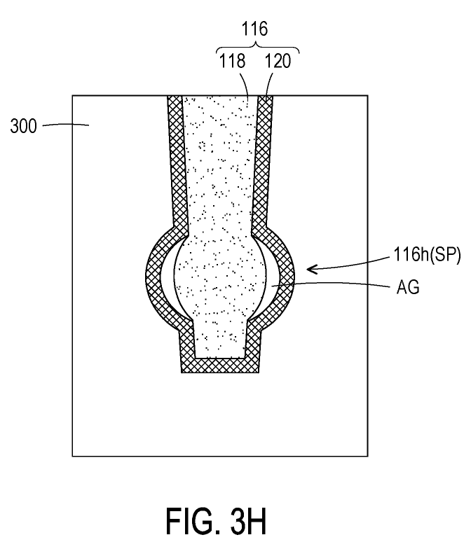

At the stage shown in FIG. 3A, a first mask layer 302 is first formed on a substrate 300, followed by forming a trench TR passing through the mask layer 302 and extending into the substrate 300. The substrate 300 may be the substrate 102 described in FIG. 1, or may be the substrate 200 described in FIG. 2. In subsequent steps, the isolation structure 116 is formed within the trench TR.

At the stage shown in FIG. 3B, a second mask layer 304 is conformally formed along the exposed surfaces of the first mask layer 302 and the substrate 300. As a result, the second mask layer 304 covers the top surface of the first mask layer 302 and the sidewalls and the bottom surface of the trench TR.

At the stage shown in FIG. 3C, the horizontally extending portions of the second mask layer 304 are removed, that is, the portions extending along the top surface of the first mask layer 302 and the portion extending along the bottom surface of the trench TR. The top surface of the first mask layer 302 is exposed, and the substrate 300 is exposed at the bottom of the trench TR. The above-mentioned patterning of the second mask layer 304 is achieved by an anisotropic etching process. Since the patterning of the second mask layer 304 may be completed without a lithography process, the patterning operation of the second mask layer 304 is also referred to as a self-aligned patterning process.

At the stage shown in FIG. 3D, an anisotropic etching process is performed using the first mask layer 302 and the second mask layer 304 as masks. The substrate 300 is etched downward from the bottom of the trench TR, further increasing the depth of the trench TR. After deepening, the bottom of the trench TR is not masked by any mask layer.

At the stage shown in FIG. 3E, an isotropic etching process is performed using the first mask layer 302 and the second mask layer 304 as masks. At this time, the substrate 300 is isotropically etched outward from the bottom of the trench TR not covered by any mask layer. The trench TR is deepened and laterally extended outward at the bottom, forming a spherical portion SP that defines the laterally protruding structure 116h of the isolation structure 116.

The anisotropic etching process described in FIG. 3D is omitted, and the isotropic etching process described in FIG. 3E is performed directly after completing the patterning of the second mask layer 304, so as to form the spherical portion SP.

At the stage shown in FIG. 3F, an anisotropic etching process is performed again using the first mask layer 302 and the second mask layer 304 as masks. Due to the high directionality of anisotropic etching, the trench TR is mainly deepened downward at this time. The trench TR further has a vertically extending portion V below the spherical portion SP.

At the stage shown in FIG. 3G, the second mask layer 304 is removed, and subsequently, the insulating liner 120 of the isolation structure 116 is conformally formed along the surface of the trench TR. The process of forming the insulating liner 120 includes performing a planarization process, which removes the first mask layer 302 and the portions of the insulating liner 120 above the surface of the substrate 300.

Next, at the stage shown in FIG. 3H, the insulating fill material 118 of the isolation structure 116 is filled into the trench TR. The insulating liner 120 and the insulating fill material 118 formed in the spherical portion SP of the trench TR become the laterally protruding structure 116h of the isolation structure 116. A physical vapor deposition process is used to form the insulating fill material 118, and the process conditions are adjusted so that the insulating fill material 118 does not completely fill the spherical portion SP of the trench TR, thereby forming the air gap AG between the insulating liner 120 and the insulating fill material 118 within the spherical portion SP.

In FIG. 1, the isolation structure 116 may be formed first, followed by the completion of the manufacturing of the transistor device 100. In FIG. 2, the isolation structure 116 may be formed first to define multiple active regions 202, and then the access transistors AT are formed in the active regions 202. After completing the manufacturing of the access transistors AT, contact structures, bit lines, and storage capacitors are formed on the substrate 200.

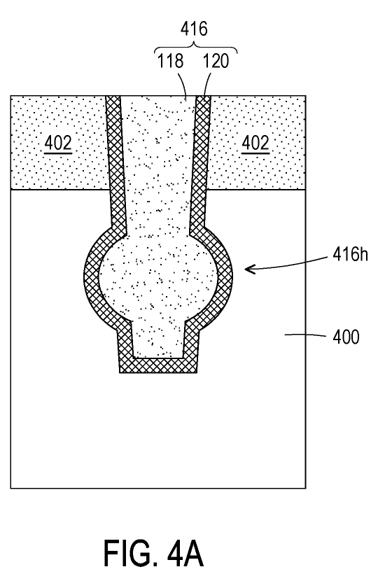

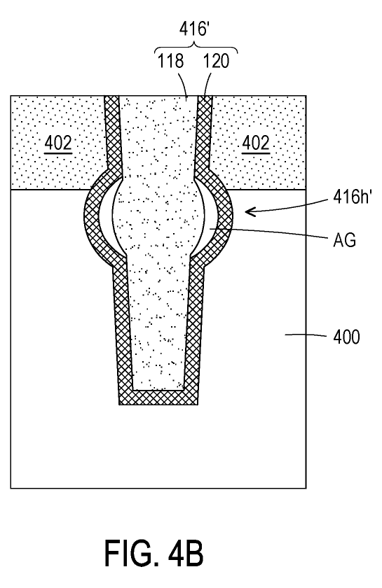

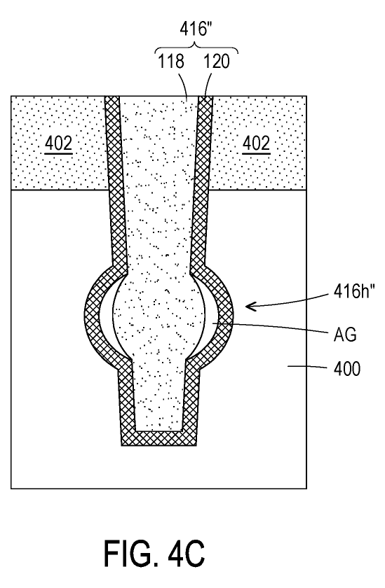

An isolation structure 416 shown in FIG. 4A is similar to the isolation structure 116 shown in FIGS. 1 and 2 , except that the isolation structure 416 shown in FIG. 4A does not have the air gap AG. Specifically, at a laterally protruding structure 416h of the isolation structure 416, the insulating fill material 118 expands laterally outward to contact the insulating liner 120, such that no air gap exists between the insulating fill material 118 and the insulating liner 120. Although there is no air gap, the laterally protruding structure 416h of the isolation structure 416 still blocks the leakage path LK (as shown in FIGS. 1 and 2 ) by extending through the leakage path LK.

Moreover, a substrate 400 shown in FIG. 4A may be the substrate 102 described in FIG. 1 or the substrate 200 described in FIG. 2. Furthermore, a contact structure 402 shown in FIG. 4A may be the drain/source structure 114 described in FIG. 1 or the doped region 212 described in FIG. 2.

The top end of the laterally protruding structure 116h of the isolation structure 116 shown in FIG. 1 is located below the bottom surface of the drain/source structure 114. Similarly, the top end of the laterally protruding structure 116h of the isolation structure 116 shown in FIG. 2 is located below the bottom surface of the doped region 212, and the top end of the laterally protruding structure 416h of the isolation structure 416 in FIG. 4A is lower than the bottom surface of the contact structure 402. On the other hand, the top end of a laterally protruding structure 416h' of an isolation structure 416' in FIG. 4B is higher than the bottom surface of the contact structure 402, while the bottom end of the laterally protruding structure 416h' is lower than the bottom surface of the contact structure 402. Furthermore, compared to the isolation structures 116 and 416, the bottom of the isolation structure 416' extends downward from the bottom end of the laterally protruding structure 416h' to a greater depth, thus providing improved electrical isolation effects.

Within the laterally protruding structure 416h', there is the air gap AG extending between the insulating fill material 118 and the insulating liner 120. However, at the laterally protruding structure 416h', the insulating fill material 118 expands laterally outward to contact the insulating liner 120, such that no air gap exists between the insulating fill material 118 and the insulating liner 120.

Compared to moving the laterally protruding structure of the isolation structure upward as shown in FIG. 4B, FIG. 4C illustrates that the laterally protruding structure of the isolation structure may also be moved downward. In comparison with the isolation structure 116 shown in FIGS. 1 and 2 and the isolation structure 416 shown in FIG. 4A, an isolation structure 416'' shown in FIG. 4C has a laterally protruding structure 416h'' that is spaced apart from the contact structure 402 above by a greater distance. Within the laterally protruding structure 416h'', there is the air gap AG extending between the insulating fill material 118 and the insulating liner 120. However, at the laterally protruding structure 416h'', the insulating fill material 118 expands laterally outward to contact the insulating liner 120, such that no air gap exists between the insulating fill material 118 and the insulating liner 120.

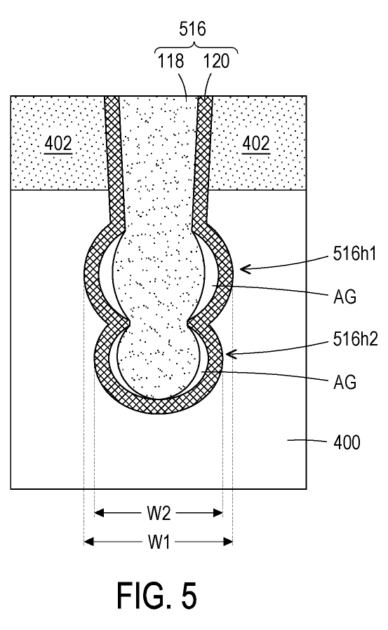

An isolation structure 516 shown in FIG. 5 is similar to the isolation structure 116 described in FIGS. 1 and 2, except that the isolation structure 516 shown in FIG. 5 has multiple laterally protruding structures, including laterally protruding structure 516h1 and laterally protruding structure 516h2. The laterally protruding structure 516h1 laterally protrudes with respect to a vertically extending body portion of the isolation structure 516 below the contact structure 402, while the laterally protruding structure 516h2 laterally protrudes with respect to a vertically extending body portion of the isolation structure 516 below the laterally protruding structure 516h1. In some embodiments, the bottom end of the laterally protruding structure 516h2 defines the bottom end of the isolation structure 516. Additionally, the top end of the laterally protruding structure 516h2 may contact the bottom end of the laterally protruding structure 516h1. Alternatively, the top end of the laterally protruding structure 516h2 may be vertically spaced apart from the bottom end of the laterally protruding structure 516h1.

A width W1 of the laterally protruding structure 516h1 is greater than a width W2 of the laterally protruding structure 516h2. Furthermore, in some embodiments, at least one of the laterally protruding structures 516h1 and 516h2 may contain the air gap AG extending between the insulating fill material 118 and the insulating liner 120.

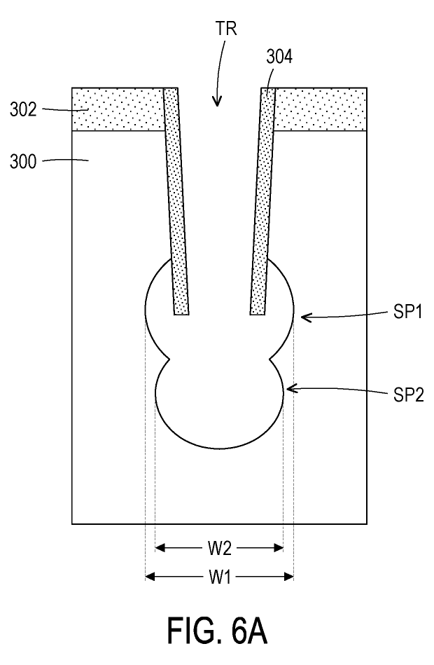

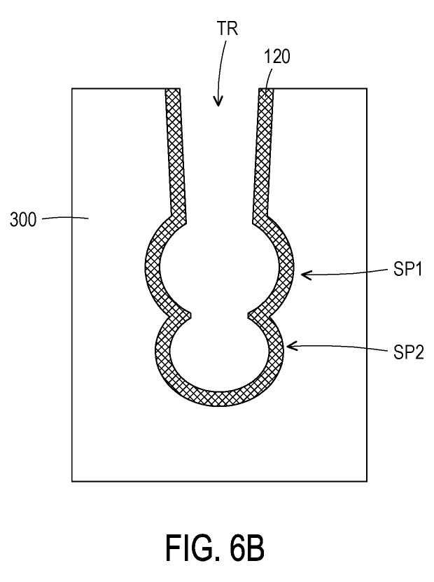

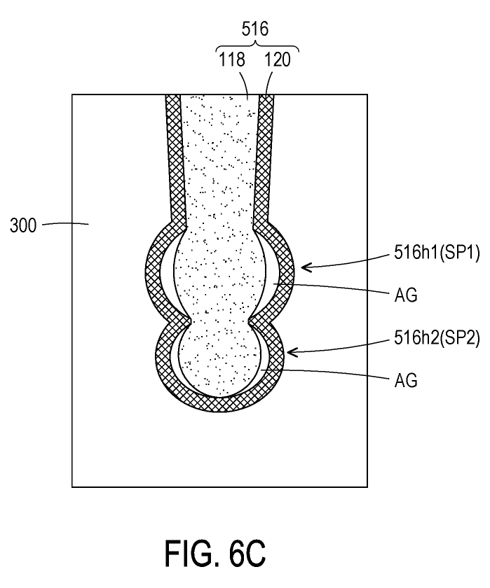

This process is similar to the process described in FIGS. 3A to 3H , except for differences after the step described in FIG. 3F. Specifically, after performing the anisotropic etching process to form the vertically extending portion V of the trench TR (as shown in FIG. 3F), an isotropic etching process is performed again in the stage shown in FIG. 6A. As a result, the spherical portion SP of the trench TR that is not masked by the second mask layer 304 further expands laterally to form a spherical portion SP1, and the vertically extending portion V expands laterally outward to form a spherical portion SP2. In subsequent steps, the laterally protruding structure 516h1 of the isolation structure 516 fills in the spherical portion SP1, while the laterally protruding structure 516h2 of the isolation structure 516 fills in the spherical portion SP2. Since the formation of the spherical portion SP1 involves two isotropic etching processes while the formation of the spherical portion SP2 involves merely one isotropic etching process, the width of the spherical portion SP1 (that is, the width W1 of the laterally protruding structure 516h1) is greater than the width of the spherical portion SP2 (that is, the width W2 of the laterally protruding structure 516h2).

At the stage shown in FIG. 6B, the second mask layer 304 is removed, and subsequently, the insulating liner 120 of the isolation structure 516 is conformally formed along the surface of the trench TR. The process of forming the insulating liner 120 includes performing a planarization process, which removes the first mask layer 302 and the portions of the insulating liner 120 above the surface of the substrate 300.

Next, at the stage shown in FIG. 6C, the insulating fill material 118 of the isolation structure 516 is filled into the trench TR. The insulating liner 120 and the insulating fill material 118 formed in the spherical portion SP1 of the trench TR become the laterally protruding structure 516h1 of the isolation structure 516, while the insulating liner 120 and the insulating fill material 118 formed in the spherical portion SP2 of the trench TR become the laterally protruding structure 516h2 of the isolation structure 516. A physical vapor deposition process is used to form the insulating fill material 118, and the process conditions are adjusted so that the insulating fill material 118 does not completely fill the spherical portion SP1 and/or the spherical portion SP2 of the trench TR, thereby forming the air gap AG between the insulating liner 120 and the insulating fill material 118 within the spherical portion SP1 and/or the spherical portion SP2.

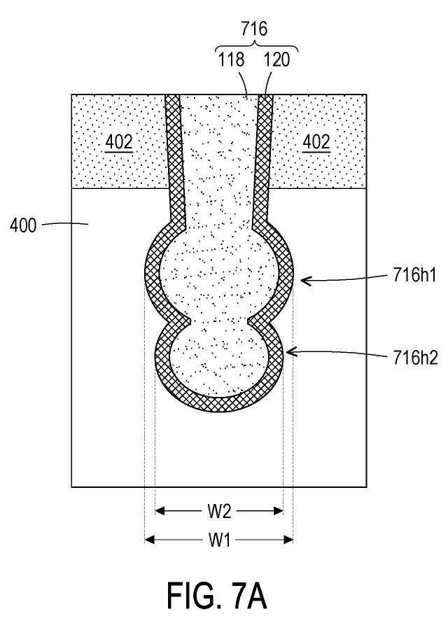

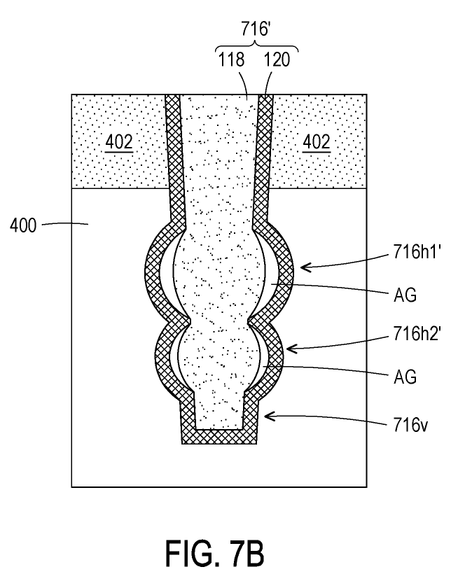

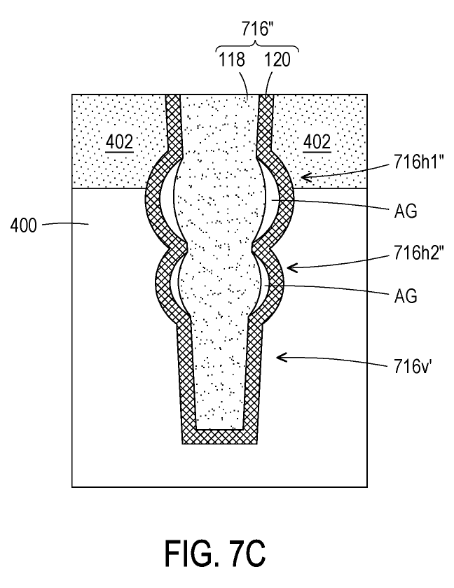

An isolation structure 716 shown in FIG. 7A is similar to the isolation structure 516 described in FIG. 5, except that the laterally protruding structures 716h1, 716h2 of the isolation structure 716 do not have air gaps. At the laterally protruding structures 716h1 and 716h2, the insulating fill material 118 expands laterally outward to contact the insulating liner 120, such that no air gap exists between the insulating fill material 118 and the insulating liner 120.

An isolation structure 716' shown in FIG. 7B is also similar to the isolation structure 516 described in FIG. 5, except that a laterally protruding structure 716h2' located below the laterally protruding structure 716h1' of the isolation structure 716' is not at the bottommost part of the isolation structure 716'. Specifically, the isolation structure 716' further includes a bottom vertically extending structure 716v that extends downward from the laterally protruding structure 716h2' to the bottommost end of the isolation structure 716'.

The manufacturing method for the isolation structure 716' is similar to the method shown in FIGS. 6A to 6C , except that after forming the spherical portions SP1, SP2 of the trench TR, an additional anisotropic etching process may be further performed to etch the substrate 400 downward from the bottom of the spherical portion SP2 to form a vertically extending portion of the trench TR. In subsequent steps, the insulating liner 120 and the insulating fill material are formed in this vertically extending portion of the trench TR, thereby forming the bottom vertically extending structure 716v of the isolation structure 716'.

In addition, within the laterally protruding structure 716h1' and/or the laterally protruding structure 716h2', there is the air gap AG extending between the insulating fill material 118 and the insulating liner 120. However, at the laterally protruding structures 716h1', 716h2', the insulating fill material 118 expands laterally outward to contact the insulating liner 120, such that no air gap exists between the insulating fill material 118 and the insulating liner 120.

An isolation structure 716'' shown in FIG. 7C is similar to the isolation structure 716' described in FIG. 7B, except that the laterally protruding structures 716h1'', 716h2'' of the isolation structure 716'' are moved upward, such that the top end of the laterally protruding structure 716h1'' located above the laterally protruding structure 716h2'' is higher than the bottom surface of the contact structure 402. Corresponding to the upward movement of the laterally protruding structures 716h1'', 716h2'', a bottom vertically extending structure 716v' of the isolation structure 716'' extends downward from a greater height to the bottom end of the isolation structure 716'', and may have a greater height compared to the vertically extending structure 716v shown in FIG. 7B.

Within the laterally protruding structure 716h1'' and/or the laterally protruding structure 716h2'', there is the air gap AG extending between the insulating fill material 118 and the insulating liner 120. However, at the laterally protruding structures 716h1'', 716h2'', the insulating fill material 118 expands laterally outward to contact the insulating liner 120, such that no air gap exists between the insulating fill material 118 and the insulating liner 120.

Despite various modifications, the isolation structure provided by this disclosure can interrupt surrounding leakage paths based on one or more laterally protruding structures, thus providing improved electrical isolation effects. Although this disclosure illustrates the isolation structure with one or two laterally protruding structures, in practice, the isolation structure may have three or more laterally protruding structures in specific products. Furthermore, the isolation structure described in this disclosure is not limited to applications in the logic circuit and memory circuit described in FIGS. 1 and 2 , but may be applied to various semiconductor device structures that require isolation structures to ensure electrical isolation between adjacent components.

What is claimed is:

1. A semiconductor device structure, comprising:
a first transistor device and a second transistor device comprising a first contact structure and a second contact structure adjacent to each other and in a surface region of a substrate; and
an isolation structure extending between the first contact structure and the second contact structure in the substrate, and having at least one laterally protruding structure laterally protruding with respect to a vertically extending body portion of the isolation structure, wherein the at least one laterally protruding structure is at least partially located below the first contact structure and the second contact structure.

2. The semiconductor device structure according to claim 1, wherein the isolation structure comprises an insulating fill material and an insulating liner lining sidewalls and a bottom surface of the insulating fill material.

3. The semiconductor device structure according to claim 2, wherein the at least one laterally protruding structure comprises an air gap extending between the insulating fill material and the insulating liner.

4. The semiconductor device structure according to claim 2, wherein the insulating fill material is silicon nitride, and the insulating liner is formed by silicon oxide.

5. The semiconductor device structure according to claim 1, wherein the at least one laterally protruding structure of the isolation structure is entirely located below the first contact structure and the second contact structure.

6. The semiconductor device structure according to claim 1, wherein a topmost end of the at least one laterally protruding structure of the isolation structure is higher than a bottom end of the first contact structure and the second contact structure.

7. The semiconductor device structure according to claim 1, wherein the at least one laterally protruding structure of the isolation structure comprises a first laterally protruding structure and a second laterally protruding structure located below the first laterally protruding structure arranged along a vertical direction, and a width of the first laterally protruding structure is greater than a width of the second laterally protruding structure.

8. The semiconductor device structure according to claim 1, wherein a topmost end of the first laterally protruding structure of the isolation structure is higher than a bottom end of the first contact structure and the second contact structure, and the second laterally protruding structure of the isolation structure is entirely located below the first contact structure and the second contact structure.

9. The semiconductor device structure according to claim 1, wherein the isolation structure further comprises a bottom vertically extending structure that extends downward from the second laterally protruding structure to a bottommost end of the isolation structure.

10. The semiconductor device structure according to claim 1, wherein the isolation structure gradually narrows from a topmost end of the at least one laterally protruding structure downward, and has a greatest width at the laterally protruding structure.

11. A manufacturing method of a semiconductor device structure, comprising:
forming an isolation structure in a substrate, wherein the isolation structure has at least one laterally protruding structure laterally protruding with respect to a vertically extending body portion of the isolation structure; and
forming a first transistor device and a second transistor device on both sides of the isolation structure, wherein the first transistor device and the second transistor device comprise a first contact structure and a second contact structure spaced apart by the isolation structure and in a surface region of the substrate, and the at least one laterally protruding structure of the isolation structure is at least partially located below the first contact structure and the second contact structure.

12. The manufacturing method of the semiconductor device structure according to claim 11, wherein a method of forming the isolation structure comprises:
forming a trench at a surface of the substrate;
forming a mask layer along sidewalls of the trench;
performing an isotropic etching process to expand outward a bottom of the trench into a spherical portion;
etching the substrate downward from a bottom of the spherical portion;
removing the mask layer; and
filling the isolation structure in the trench.

13. The manufacturing method of the semiconductor device structure according to claim 12, wherein filling the isolation structure in the trench comprises:
forming an insulating liner along a surface of the trench; and
filling an insulating fill material in the trench.

14. The manufacturing method of the semiconductor device structure according to claim 12, wherein the insulating fill material is silicon nitride, and the insulating liner is formed by silicon oxide.

15. The manufacturing method of the semiconductor device structure according to claim 11, wherein a method of forming the isolation structure comprises:
forming a trench at a surface of the substrate;
forming a mask layer along sidewalls of the trench;
performing a first isotropic etching process to expand outward a bottom of the trench into a first spherical portion;
etching the substrate downward from a bottom of the first spherical portion;
performing a second isotropic etching process to further expand outward the first spherical portion, and to expand outward a current bottom of the trench into a second spherical portion;
removing the mask layer; and
filling the isolation structure in the trench.

16. The manufacturing method of the semiconductor device structure according to claim 15, wherein a method of forming the isolation structure comprises:
performing an anisotropic etching process to etch the substrate downward from a bottom of the second spherical portion to form a vertically extending portion of the trench.

17. The manufacturing method of the semiconductor device structure according to claim 16, wherein after the isolation structure is filled in the trench, a bottom vertically extending structure is formed by the vertically extending portion.
